(19) United States
(12) Patent Application Publication
(10) Pub. No.: US 2026/0215239 A1
(43) Pub. Date: Jul. 23, 2026

(54) MANUFACTURING A SECOND SEMICONDUCTOR ITEM WHILE CONCURRENTLY FORMING VIA HOLES AND LINE HOLES

(71) Applicant: Tower Semiconductor Ltd., Migdal Haemek (IL)

(72) Inventors: Alex Sirkis, Yokneam Illit (IL); Marina Gudinetzky, Nesher (IL); Gerardo Cappa, Monza (IL)

(73) Assignee: Tower Semiconductor Ltd., Migdal Haemek (IL)

(21) Appl. No.: 19/034,524

(22) Filed: Jan. 22, 2025

(51) Int. Cl. H01L 21/768; H01L 23/522

(52) U.S. Cl. CPC H10W 20/082; H10W 20/42

(57) ABSTRACT

There is provided a method for manufacturing a second semiconductor item, the method comprising: (a) obtaining a first semiconductor item that includes (i) a first mask that comprises first apertures of a first width, (ii) a main dielectric layer that has a first PER, (iii) a VEBCD layer located below the main dielectric layer, the VEBCD layer exhibits a second PER that exceeds the first PER, and (iv) an additional metal layer located below the VEBCD layer that comprises additional metal conductors; (b) forming intermediate holes in the main dielectric layer at locations allocated to vias holes, the intermediate holes have a second width that is smaller than the first width and do not reach the VEBCD layer; and (c) concurrently forming the via holes and line holes to provide the second semiconductor item by applying an etching process while utilizing the VEBCD layer to prevent a width of bottoms of the via holes from exceeding a width of the additional metal conductors.

### BACKGROUND OF THE INVENTION

Semiconductor devices are formed by a manufacturing process that is required to provide smaller semiconductor devices at lower cost and at shorter manufacturing periods.

A semiconductor device usually include (a) external contacts, (b) conductors (made of metal or metal alloys) that are positioned between dielectric materials and are spread among different metal layers and (c) semiconductor elements such as diodes, capacitors, resistors and transistors. Line holes and vias are used for electrically coupling external contacts, semiconductor elements, and conductors.

There is a growing need to speed up the simplify the formation of a second semiconductor item that include via holes and line holes.

### SUMMARY

According to an embodiment, there is provided a method for manufacturing a second semiconductor item, the method includes (a) obtaining a first semiconductor item that comprises (i) a first mask that comprises first apertures of a first width, (ii) a main dielectric layer that has a first polymerization to etch ratio (PER), (iii) a via bottom etch control dielectric (VEBCD) layer located below the main dielectric layer, the VEBCD layer exhibits a second PER that exceeds the first PER, and (iv) an additional metal layer located below the VEBCD layer that comprises additional metal conductors; (b) forming intermediate holes in the main dielectric layer at locations allocated to vias holes, the intermediate holes have a second width that is smaller than the first width and do not reach the VEBCD layer; and (c)concurrently forming the via holes and line holes to provide the second semiconductor item by applying an etching process while utilizing the VEBCD layer to prevent a width of bottoms of the via holes from exceeding a width of the additional metal conductors.

According to an embodiment, there is provided a second semiconductor item, that includes (a) a main dielectric layer that has a first polymerization to etch ratio (PER), (b) a via bottom etch control dielectric (VEBCD) layer located below the main dielectric layer, the VEBCD layer exhibits a second PER that exceeds the first PER, (c) an additional metal layer located below the VEBCD layer that comprises additional metal conductors; (d) line holes; and (e) via holes, wherein each of the via holes comprises an upper portion and a middle portion that pass through the main dielectric layer and a lower portion that passes through at least the VEBCD layer; and wherein the middle portion has a first slope, the lower portion has a second slope that exceeds the first slope.

According to an embodiment, there is provided a second semiconductor item, that includes a main dielectric layer that has a first polymerization to etch ratio (PER), a via bottom etch control dielectric (VEBCD) layer located below the main dielectric layer, the VEBCD layer exhibits a second PER that exceeds the first PER, an additional metal layer located below the VEBCD layer that comprises additional metal conductors; line holes; and via holes, wherein the second semiconductor item being manufactured by a manufacturing process that includes (a) obtaining a first semiconductor item that comprises (i) a first mask that comprises first apertures of a first width, (ii) the main dielectric layer, (iii) the VEBCD layer, and (iv) the additional metal layer; (b) forming intermediate holes in the main dielectric layer at locations allocated to the vias holes, the intermediate holes have a second width that is smaller than the first width and do not reach the VEBCD layer; and (c) concurrently forming the via holes and line holes to provide the second semiconductor item by applying an etching process while utilizing the VEBCD layer to prevent a width of bottoms of the via holes from exceeding a width of the additional metal conductors.

### BRIEF DESCRIPTION OF THE DRAWINGS

The subject matter being regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates an example of a method;

FIGS. 2-8 illustrates an example of an implementations of various steps of the method of FIG. 1 and of a first and second semiconductor items.

### DESCRIPTION OF THE PREFERRED EMBODIMENTS

According to an embodiment there is provided a manufacturing process that speeds up and simplifies the formation of line holes and via holes by (i) forming intermediate holes in a main dielectric layer at locations allocated to vias holes, and (ii) concurrently forming the of line holes and via holes and controlling the formation of the via holes so that width of bottoms of the via holes are aligned with and do not exceed width of the additional metal conductors.

The control is based on narrowing the bottom of the via holes using a via bottom etch control dielectric (VEBCD) layer located below the main dielectric layer, whereas the VEBCD layer exhibits a second polymerization to etch ratio (PER) that is higher than a first PER of the main dielectric layer—thereby increasing the amount of etching process polymer residuals—thereby forming a thicker portion of a layer of etching process polymer residuals over the VEBCD layer.

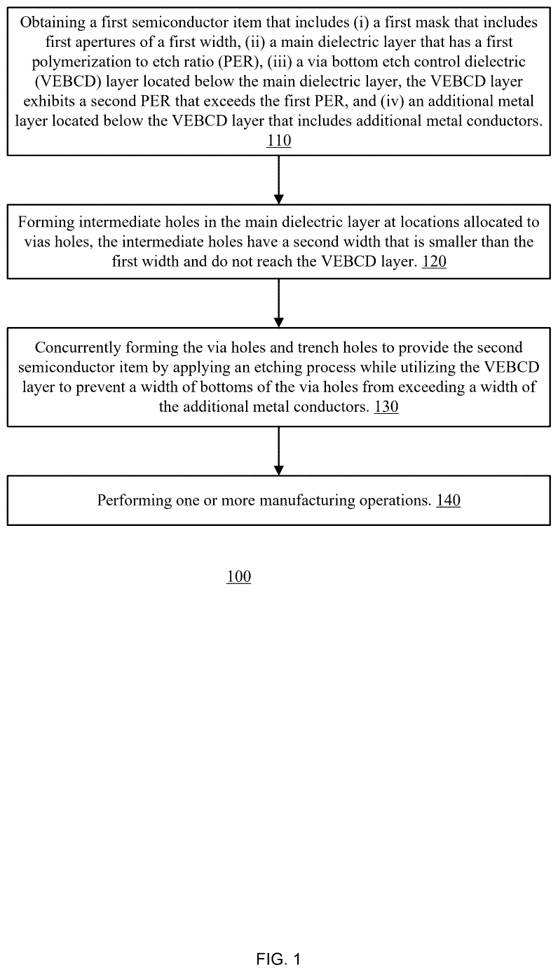

FIG. 1 illustrates an example of method 100 for forming a second semiconductor item.

According to an embodiment, method 100 includes step 110 of obtaining a first semiconductor item that includes (i) a first mask that includes first apertures of a first width, (ii) a main dielectric layer that has a first polymerization to etch ratio (PER), (iii) a via bottom etch control dielectric (VEBCD) layer located below the main dielectric layer, the VEBCD layer exhibits a second PER that exceeds the first PER, and (iv) an additional metal layer located below the VEBCD layer that includes additional metal conductors.

According to an embodiment step 110 includes (a) manufacturing the first semiconductor item, (b) receiving the first semiconductor item, or (c) receiving an intermediate region and performing one or more manufacturing operations to obtain the first semiconductor item. For example—forming the first mask using photoresist patterning and an initial etching process.

According to an embodiment, the VEBCD layer is a TEOS layer.

According to an embodiment, the main dielectric layer is a silicon carbide (SiOC) layer.

According to an embodiment, the second PER exceeds the first PER by a ten to one hundred percent.

According to an embodiment, the second PER exceeds the first PER by more than one hundred percent.

According to an embodiment, a thickness of the main dielectric layer ranges between three hundred and fifty nanometers and four hundred and fifty nanometers, and a width of the VEBCD layer ranges between forty nanometers and one hundred nanometers.

According to an embodiment, the first semiconductor item also includes a further dielectric layer that is located below the VEBCD layer. According to an embodiment, the further dielectric layer is made of silicon carbon nitride (SiCN). According to an embodiment, the thickness of the further dielectric layer ranges between thirty five nanometers to forty five nanometers.

According to an embodiment, step 110 is followed by step 120 of forming intermediate holes in the main dielectric layer at locations allocated to vias holes, the intermediate holes have a second width that is smaller than the first width and do not reach the VEBCD layer.

According to an embodiment, step 120 includes patterning a photoresist and etching. The intermediate holes are formed at a center of the first apertures.

According to an embodiment, step 120 is followed by step 130 of concurrently forming the via holes and line holes (also referred to as trench holes) to provide the second semiconductor item by applying an etching process while utilizing the VEBCD layer to prevent a width of bottoms of the via holes from exceeding a width of the additional metal conductors.

The forming of the intermediate holes and the VEBCD layer allows the etching process to form openings that reach the additional metal conductors—while the line holes formed at locations not allocated to the via holes pass through only a portion of the main dielectric layer—and does not reach the additional metal conductors.

Accordingly—the same chemistry is used (during the etching process of step 130) to form the via holes and line holes—while the via holes shaped are amended (in relation to their shape at the absence of the VEBCD layer). The line holes may have vertical sidewalls.

According to an embodiment, each of the via holes includes an upper portion and a middle portion that pass through the main dielectric layer and a lower portion that passes through at least the VEBCD layer; and wherein the middle portion has a first slope, the lower portion has a second slope that exceeds the first slope.

According to an embodiment, at least a majority of each of the via holes is coated with a layer of etching process polymer residuals.

According to an embodiment, an average thickness of the layer of etching process polymer residuals at the middle portion is smaller than an average thickness of the layer of etching process polymer residuals at the lower portion.

According to an embodiment, step 130 is followed by step 140 of performing one or more manufacturing operations. For example—filling the line holes and the via holes with metal, performing another iteration of at least steps 120 and 130 to reach and couple conductors of yet a further metal layer, and the like.

According to an embodiment, method 100 and especially step 130 apply a dual damascene manufacturing process.

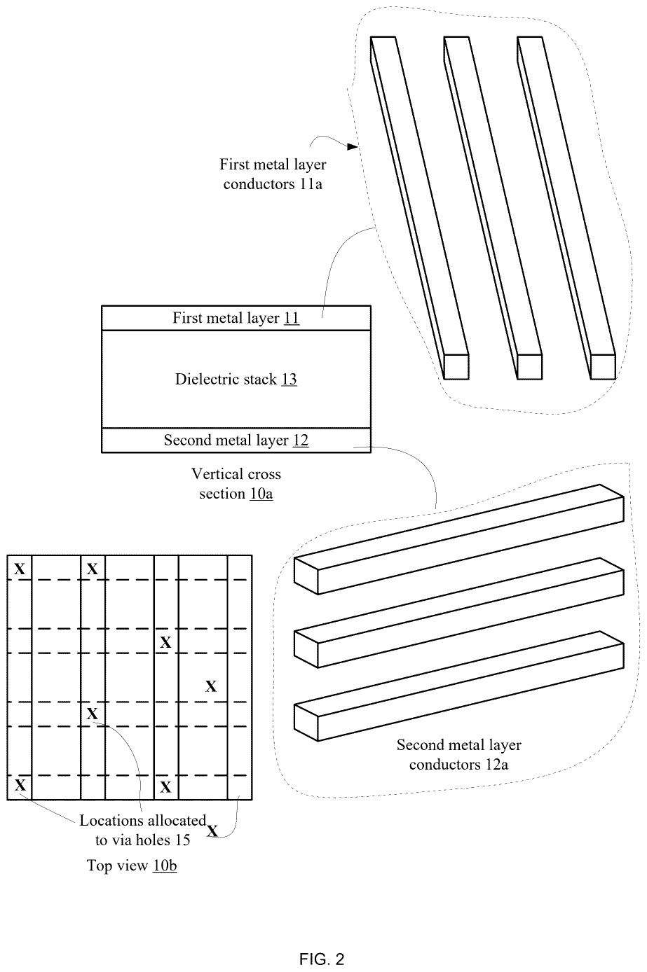

FIG. 2 illustrates an example of the locations allocated to via holes (denoted X) 15, selected out of virtual intersection points (seen in top view 10b) between first metal layer conductors 11a of first metal layer 11 and second metal layer conductors 12a of second metal layer 12 that is located below dielectric stack 13 positioned between the first metal layer 11 and the second metal layer 12.

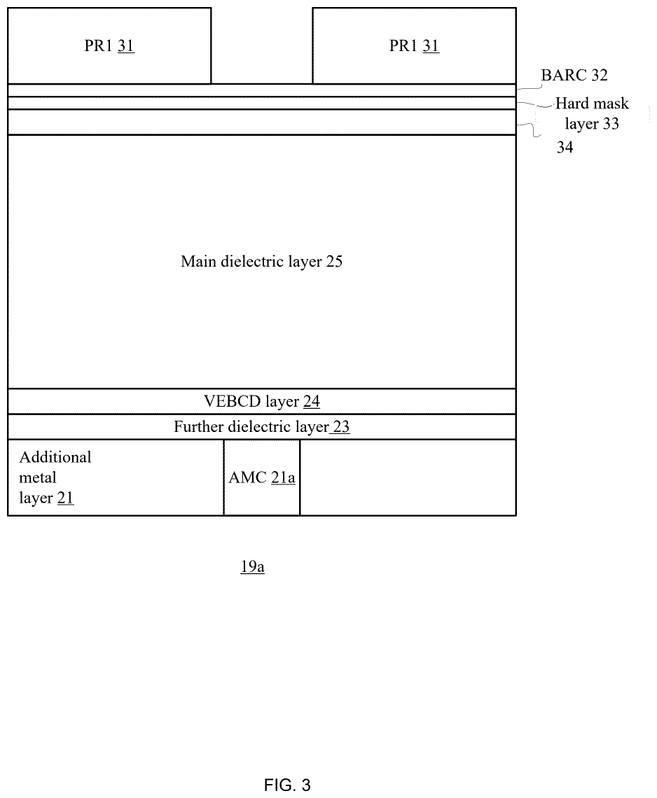

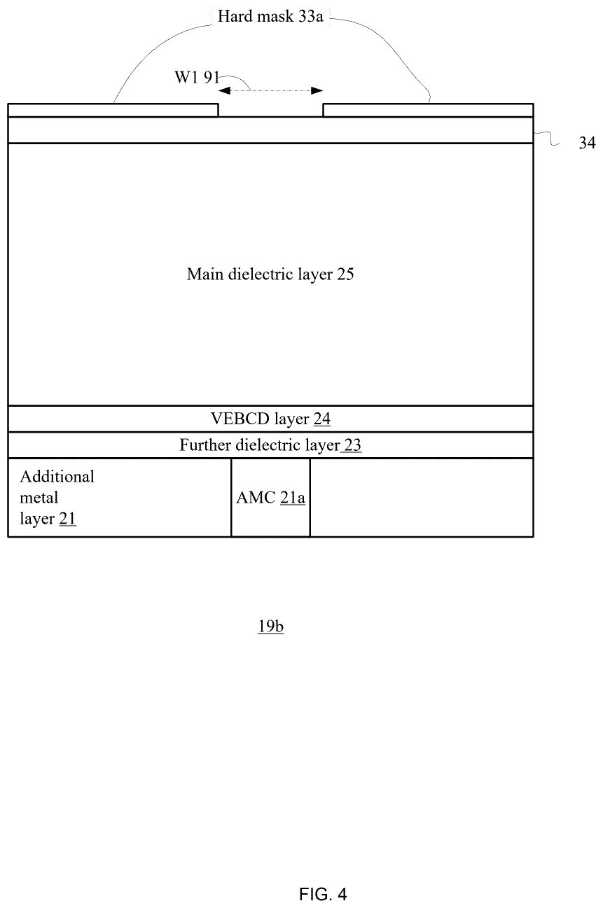

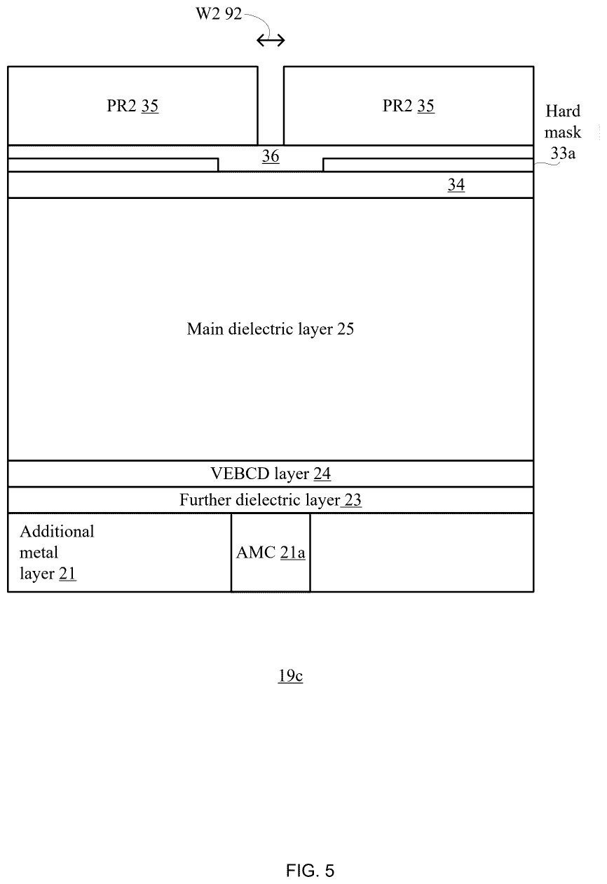

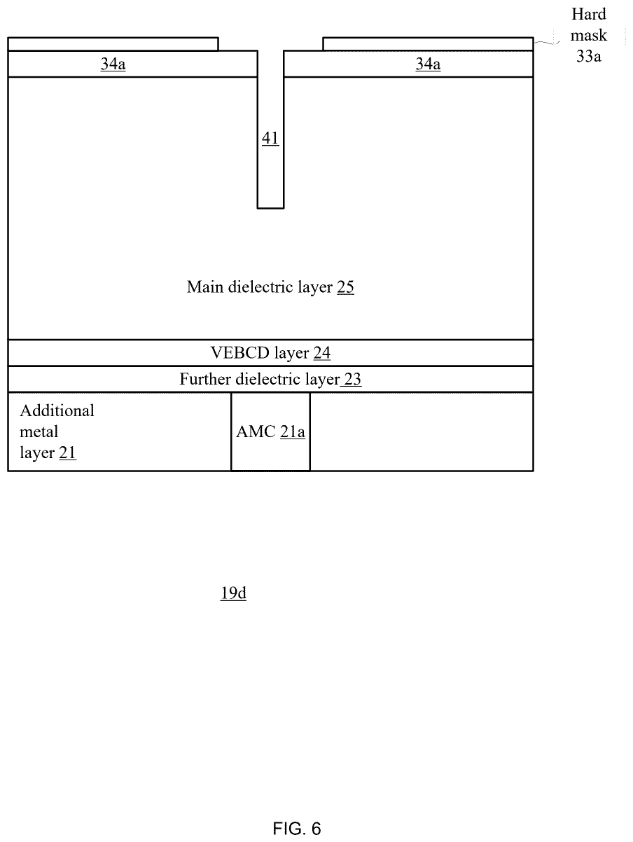

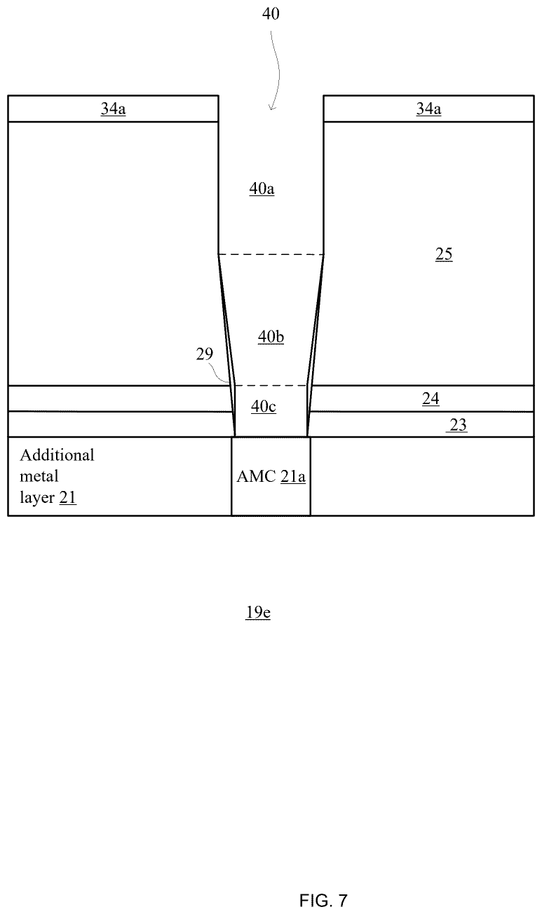

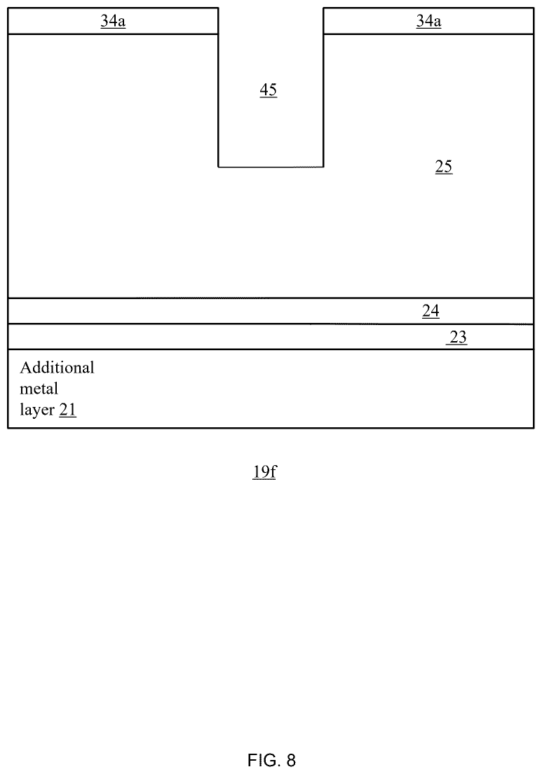

FIGS. 3-8 illustrates an example of an implementation of different steps of method 100. FIGS. 3-4 are examples of an implementation of step 110. FIGS. 5-6 illustrate an example of an implementation of step 120. FIGS. 7-8 are examples of an implementation of step 130.

Referring to FIG. 3—initial semiconductor item 19a includes (from top to bottom): first photoresist segments (PR1 31) that are spaced apart from each other, bottom anti-reflective coatings (BARC 32), hard mask layer 33, further dielectric layer 34, main dielectric layer 25, VEBCD layer 24, further dielectric layer 23 and additional metal layer 21 that includes additional metal conductors (such as AMC 21a).

FIG. 4 illustrates a first semiconductor item 19a following a removal of the first photoresist segments and the BARC segment and after the hard mask layer was processed to provide hard mask 33a having apertures of a first width (W1 91).

FIG. 5 illustrates a preparation to the formation of an intermediate hole—and additional semiconductor item 19c includes (from top to bottom) second photoresists segments (denoted PR2 35) that are spaced from each other by a second width (W2 92), another dielectric layer 36 that also fills hard mask 33a apertures, a further dielectric layer 34, main dielectric layer 25, VEBCD layer 24, further dielectric layer 23 and additional metal layer 21 that includes additional metal conductors (such as AMC 21a).

FIG. 6 illustrates the outcome of the formation of the intermediate hole 41. The second photoresists segments and the other dielectric layer 36 were removed and the intermediate hole passed through a part of the main dielectric layer 25 and segments the further dielectric layer to further dielectric layer segments 34a.

FIGS. 7 and 8 illustrates an outcome of a concurrently forming of a via hole (denoted 40 in FIG. 7) and a line hole (denoted 45 in FIG. 8).

FIG. 7 illustrates that the via hole 40 includes an upper portion 40a and a middle portion 40b that pass through the main dielectric layer 25 and a lower portion 40c that passes through at least the VEBCD layer 24.

The middle portion 40b has a first slope and the lower portion 40c has a second slope that exceeds the first slope.

In FIG. 7 the lower portion is vertical—but it may be oriented by an angle that differs than ninety degrees.

According to an embodiment, at least fifty precent (a majority) of via hole 40 is coated with a layer of etching process polymer residuals 29.

It should be noted that a cross section of the layer of etching process polymer residuals may be rounded, non-linear, may include more than two facets, and the like.

According to an embodiment, an average thickness of the layer of etching process polymer residuals 9 at the middle portion 40b is smaller than an average thickness of the layer of etching process polymer residuals 9 at the lower portion 40c.

FIG. 8 illustrates a line hole 45 that passes only through a portion of the main dielectric layer.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

In the foregoing detailed description, numerous specific details are set forth to provide a thorough understanding of the invention. However, it will be understood by those skilled in the art that the present invention may be practiced without these specific details. In other instances, well-known methods, procedures, and components have not been described in detail so as not to obscure the present invention.

The subject matter being regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

The term “and/or” means additionally or alternatively. For example—A and/or B—may mean only A, only B, or both A and B.

Any reference to any of the terms “comprise”, “comprises”, “comprising” “including”, “may include” and “includes” may be applied, mutatis mutandis, to any of the terms “consists”, “consisting”, “consisting essentially of”.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim

1. A method for manufacturing a second semiconductor item, the method comprising:
(a) obtaining a first semiconductor item that comprises (i) a first mask that comprises first apertures of a first width, (ii) a main dielectric layer that has a first polymerization to etch ratio (PER), (iii) a via bottom etch control dielectric (VEBCD) layer located below the main dielectric layer, the VEBCD layer exhibits a second PER that exceeds the first PER, and (iv) an additional metal layer located below the VEBCD layer that comprises additional metal conductors;
(b) forming intermediate holes in the main dielectric layer at locations allocated to vias holes, the intermediate holes have a second width that is smaller than the first width and do not reach the VEBCD layer; and
(c) concurrently forming the via holes and line holes to provide the second semiconductor item by applying an etching process while utilizing the VEBCD layer to prevent a width of bottoms of the via holes from exceeding a width of the additional metal conductors.

2. The method according to claim 1, wherein the VEBCD layer is a TEOS layer.

3. The method according to claim 1, wherein the main dielectric layer is a SiOC layer.

4. The method according to claim 1, wherein the forming of the intermediate holes comprises patterning a photoresist and etching, wherein the intermediate holes are formed at a center of the first apertures.

5. The method according to claim 1, wherein each of the via holes comprises an upper portion and a middle portion that pass through the main dielectric layer and a lower portion that passes through at least the VEBCD layer; and wherein the middle portion has a first slope, the lower portion has a second slope that exceeds the first slope.

6. The method according to claim 5, wherein at least a majority of each of the via holes is coated with a layer of etching process polymer residuals.

7. The method according to claim 6, wherein an average thickness of the layer of etching process polymer residuals at the middle portion is smaller than an average thickness of the layer of etching process polymer residuals at the lower portion.

8. The method according to claim 1, wherein the second PER exceeds the first PER by a ten to one hundred percent.

9. The method according to claim 1, wherein the second PER exceeds the first PER by more than one hundred percent.

10. The method according to claim 1, wherein a thickness of the main dielectric layer ranges between three hundred and fifty nanometers and four hundred and fifty nanometers, and a width of the VEBCD layer ranges between forty nanometers and one hundred nanometers.

11. A second semiconductor item, comprising:
a main dielectric layer that has a first polymerization to etch ratio (PER),
a via bottom etch control dielectric (VEBCD) layer located below the main dielectric layer, the VEBCD layer exhibits a second PER that exceeds the first PER,
an additional metal layer located below the VEBCD layer that comprises additional metal conductors;
line holes; and
via holes, wherein each via hole of the via holes comprises an upper portion and a middle portion that pass through the main dielectric layer and a lower portion that passes through at least the VEBCD layer; and wherein the middle portion has a first slope, the lower portion has a second slope that exceeds the first slope.

12. The second semiconductor item according to claim 11, wherein at least a majority of each of the via holes is coated with a layer of etching process polymer residuals.

13. The second semiconductor item according to claim 12, wherein an average thickness of the layer of etching process polymer residuals at the middle portion is smaller than an average thickness of the layer of etching process polymer residuals at the lower portion.

14. The second semiconductor item according to claim 11, wherein the second PER exceeds the first PER by a ten to one hundred percent.

15. The second semiconductor item according to claim 11, wherein the second PER exceeds the first PER by more than one hundred percent.

16. The method according to claim 1, wherein the VEBCD layer is a TEOS layer, and wherein the main dielectric layer is a SiOC layer.

17. The second semiconductor item according to claim 11, wherein a thickness of the main dielectric layer ranges between three hundred and fifty nanometers and four hundred and fifty nanometers, and a width of the VEBCD layer ranges between forty nanometers and one hundred nanometers.

18. The second semiconductor item according to claim 12 wherein the second semiconductor item being manufactured by a manufacturing process that comprises:
(a) obtaining a first semiconductor item that comprises (i) a first mask that comprises first apertures of a first width, (ii) the main dielectric layer, (iii) the VEBCD layer, and (iv) the additional metal layer;
(b) forming intermediate holes in the main dielectric layer at locations allocated to the vias holes, the intermediate holes have a second width that is smaller than the first width and do not reach the VEBCD layer; and
(c) concurrently forming the via holes and line holes to provide the second semiconductor item by applying an etching process while utilizing the VEBCD layer to prevent a width of bottoms of the via holes from exceeding a width of the additional metal conductors.

19. The second semiconductor item according to claim 18, wherein the forming of the intermediate holes comprises patterning a photoresist and etching, wherein the intermediate holes are formed at a center of the first apertures.
